(19) United States
(12) Patent Application Publication
(10) Pub. No.: US 2019/0213951 A1
(43) Pub. Date: Jul. 11, 2019

(54) WHITE BALANCE ADJUSTMENT METHOD AND SYSTEM FOR DISPLAY SCREEN, AND DISPLAY APPARATUS

(71) Applicants: BOE TECHNOLOGY GROUP CO., LTD., Beijing (CN); CHONGQING BOE OPTOELECTRONICS TECHNOLOGY CO., LTD., Chongqing (CN)

(72) Inventors: Jinxiang LI, Beijing (CN); Yang WANG, Beijing (CN); Junwei ZHANG, Beijing (CN); Guanzheng LI, Beijing (CN)

(21) Appl. No.: 16/199,470

(22) Filed: Nov. 26, 2018

(30) Foreign Application Priority Data
Jan. 5, 2018 (CN) 201810010124.6

(51) Int. Cl. G09G 3/3225; H01L 27/32

(52) U.S. Cl. CPC G09G 3/3225; H01L 27/3211; G09G 2320/0242; G09G 2320/0233; G09G 2300/0452; H01L 27/3244

(57) ABSTRACT

A white balance adjustment method and system for a display screen, and a display apparatus are provided. The white balance adjustment method includes: step S1, causing each pixel of at least a part of pixels of the display screen to display, with a preset grayscale, color images of sub pixels of all colors in the pixel in turn, and measuring chromaticity coordinate values and actual brightness values of the displayed color images; step S2, calculating an actual brightness ratio among actual brightness values of the sub pixels of all colors; calculating a standard brightness ratio among standard brightness values of the sub pixels of all colors when the display screen displays standard white light; and step S3, comparing the actual brightness ratio and the standard brightness ratio in case of the preset grayscale to obtain a comparison result, and adjusting grayscales of the sub pixels of all colors. (FIG. 1)

### CROSS-REFERENCE TO RELATED APPLICATION

The present application claims the priority to the Chinese Patent Application NO.2018100110124.6, filed to the State Intellectual Property Office of the People's Republic of China on Jan. 5, 2018, the disclosure of which is hereby incorporated by reference in its entirety.

### TECHNICAL FIELD

The present disclosure relates to the field of display technology, and in particular to a white balance adjustment method for a display screen, a white balance adjustment system for a display screen, and a display apparatus.

### BACKGROUND

An AMOLED display screen uses RGB pixels emitting light individually to achieve the colorization technology. It has a pure color display and a wide color gamut. White balance is a significant indicator for describing the accuracy of the white color generated by mixing three primary colors of Red (R), Green (G) and Blue (B) in the display screen. White balance abnormal may cause serious distortion of the display images on the display screen.

### SUMMARY

The present disclosure provides a white balance adjustment method for a display screen, a white balance adjustment system for a display screen, and a display apparatus.

The present disclosure provides a white balance adjustment method for a display screen which includes steps S1 to S3:

step S1, causing each pixel of at least a part of pixels of the display screen to display, with a preset grayscale, color images of sub pixels of all colors in the pixel in turn, and measuring chromaticity coordinate values and actual brightness values of the displayed color images of the sub pixels of all colors;

step S2, calculating an actual brightness ratio among actual brightness values of the sub pixels of all colors in case of the preset grayscale, based on the measured actual brightness values of the color images of the sub pixels of all colors; calculating a standard brightness ratio among standard brightness values of the sub pixels of all colors when the display screen displays standard white light in case of the preset grayscale, based on the measured chromaticity coordinate values of the color images of the sub pixels of all colors; and

step S3, comparing the actual brightness ratio and the standard brightness ratio in case of the preset grayscale to obtain a comparison result, and adjusting grayscales of the sub pixels of all colors in accordance with the comparison result to cause the display screen to display standard white light.

In an embodiment, in the step S1, causing each pixel of all pixels of the display screen to display, with a preset grayscale, color images of the sub pixels of all colors in the pixel in turn, and measuring chromaticity coordinate values and actual brightness values of the displayed color images of the sub pixels of all colors.

In an embodiment, each of the at least one pixel of the display screen comprises a red sub pixel, a green sub pixel, and a blue sub pixel, wherein the step S1 comprises:

setting a grayscale of the red sub pixel as the preset grayscale, setting a grayscale of each of the green sub pixel and the blue sub pixel as 0, displaying a red image, and measuring the chromaticity coordinate value and the actual brightness value of the displayed red image of the red sub pixel,

setting a grayscale of the green sub pixel as the preset grayscale, setting the grayscale of each of the red sub pixel and the blue sub pixel as 0, displaying a green image, and measuring the chromaticity coordinate value and the actual brightness value of the displayed green image of the green sub pixel, and

setting a grayscale of the blue sub pixel as the preset grayscale, setting the grayscale of each of the green sub pixel and the red sub pixel as 0, displaying a blue image, and measuring the chromaticity coordinate value and the actual brightness value of the displayed blue image of the blue sub pixel.

In an embodiment, the step S3 includes: S31, determining, as a reference sub pixel, a sub pixel of a color for the sub pixels of all colors which has a smallest relative difference between the actual brightness ratio and the standard brightness ratio in accordance with the comparison result; and

S32, remaining the grayscale of the reference sub pixel unchanged, and adjusting the grayscales of the sub pixels of other colors.

In an embodiment, a relative difference A for a sub pixel of a color is calculated as follows:

A=(P−P1)/P1

where P is a proportion of the actual brightness value of the sub pixel of the color in the actual brightness values of the sub pixels of all colors; and

P1 is a proportion of the standard brightness value of the sub pixel of the color in the standard brightness values of the sub pixels of all colors.

In an embodiment, the step S3 further includes: determining an adjusting direction to increase or reduce the grayscale of the sub pixel of each color in accordance with the comparison result, so as to adjust the grayscale of the sub pixel of each color based on the adjusting direction.

In an embodiment, data is transmitted in 8-bit mode in the display screen, 2⁸ grayscales with grayscale values ranging from 0 to 255 are set, and the preset grayscale is one of the grayscale values 1 to 255; or

data is transmitted in 6-bit mode in the display screen, 2⁶ grayscales with grayscale values ranging from 0 to 63 are set, and the preset grayscale is one of the grayscale values 1 to 63.

In an embodiment, the white balance adjustment method further includes step of:

S4, performing the steps S1 to S3 once with respect to each of all the grayscale values.

In an embodiment, the white balance adjustment method further includes: storing the adjusted grayscales of the sub pixels of all the colors with respect to all the grayscale values, so as to facilitate inquiring subsequently about respective adjusted grayscales of the sub pixels of all the colors, and inputting the respective adjusted grayscales as image data into the display screen to achieve white balance.

The present disclosure further provides a white balance adjustment system for a display screen which includes: a measuring element configured to cause each pixel of at least a part of pixels of the display screen to display, with a preset grayscale, color images of sub pixels of all colors in the pixel in turn, and measuring chromaticity coordinate values and actual brightness values of the displayed color images of the sub pixels of all colors;

a calculating element configured to calculate an actual brightness ratio among actual brightness values of the sub pixels of all colors in case of the preset grayscale, based on the measured actual brightness values of the color images of the sub pixels of all colors; and calculating a standard brightness ratio among standard brightness values of the sub pixels of all colors when the display screen displays standard white light in case of the preset grayscale, based on the measured chromaticity coordinate values of the color images of the sub pixels of all colors; and

a comparing and adjusting element configured to compare the actual brightness ratio and the standard brightness ratio in case of the preset grayscale to obtain a comparison result, and adjusting grayscales of the sub pixels of all colors in accordance with the comparison result to cause the display screen to display standard white light.

In an embodiment, the measuring element is configured to cause each pixel of all pixels of the display screen to display, with a preset grayscale, color images of the sub pixels of all colors in the pixel in turn, and measures chromaticity coordinate values and actual brightness values of the displayed color images of the sub pixels of all colors.

In an embodiment, the comparing and adjusting element is configured to determine, as a reference sub pixel, a sub pixel of a color for the sub pixels of all colors which has a smallest relative difference between the actual brightness ratio and the standard brightness ratio in accordance with the comparison result, remain the grayscale of the reference sub pixel unchanged, and adjust the grayscales of the sub pixels of other colors.

In an embodiment, the comparing and adjusting element is configured to calculate a relative difference A for a sub pixel of a color as follows:

A=(P−P1)/P1

where P is a proportion of the actual brightness value of the sub pixel of the color in the actual brightness values of the sub pixels of all colors; and

P1 is a proportion of the standard brightness value of the sub pixel of the color in the standard brightness values of the sub pixels of all colors.

In an embodiment, the comparing and adjusting element is further configured to determine an adjusting direction to increase or reduce the grayscale of the sub pixel of each color in accordance with the comparison result, so as to adjust the grayscales of the sub pixel of each color based on the adjusting direction.

In an embodiment, the white balance adjustment system further includes: a repeating element configured to set a next grayscale value in the grayscale values other than 0 as a new preset grayscale, and control the measuring element, the calculating element and the comparing and adjusting element to repeat working with respect to the new preset grayscale until each of all the grayscale values is set as the preset grayscale once.

In an embodiment, the white balance adjustment system further includes:

a storing element configured to store the adjusted grayscales of the sub pixels of all the colors when the display screen displays standard white light for each preset grayscale in the grayscale values other than 0, so as to facilitate inquiring subsequently about respective adjusted grayscales of the sub pixels of all the colors in case of a known grayscale for each pixel of the display screen, and inputting the respective adjusted grayscales as image data into the display screen to achieve white balance.

The present disclosure further provides a display apparatus which includes a display screen and a white balance adjustment system, wherein the white balance adjustment system is the above mentioned white balance adjustment system.

### BRIEF DESCRIPTION OF THE DRAWINGS

FIG. 1 is a general flow chart of a white balance adjustment method for a display screen provided by the present disclosure;

FIG. 2 is a flow chart of Step S3 in FIG. 1; and

FIG. 3 is a principal block diagram of a white balance adjustment system for a display screen provided by an embodiment of the present disclosure.

### DETAILED DESCRIPTION

The white balance adjustment method for a display screen, the white balance adjustment system for a display screen, and the display apparatus provided by the present disclosure will be described in detail below in conjunction with the drawings and specific embodiments in order that a person skilled in the art can understand the technical solutions of the present invention better.

Existing white balance adjustment methods for AMOLED display screen are as follows: one is to adjust an area ratio of the sub pixels of three colors of red, green and blue; the other is to adjust luminescent materials and thicknesses of luminescent layers of the sub pixels of the three colors of red, green and blue.

Display screens of different batches have different TFT characteristic and OLED characteristic. TFT characteristic and OLED characteristic may have an effect on the display. Furthermore, since TFT performance research is the key work of the entire development at present, it is required to not adjust the parameters of the display screen itself as far as possible. Therefore, it is inadvisable to realize white balance by either of the two methods as mentioned above.

In view of one of the technical problems existing in the prior art, the present disclosure provides a white balance adjustment method for a display screen, a white balance adjustment system for a display screen, and a display apparatus, which can not only achieve white balance without changing the parameters of a display screen itself, but also are applicable to multiple batches of display screens with different TFT characteristics and OLED characteristics.

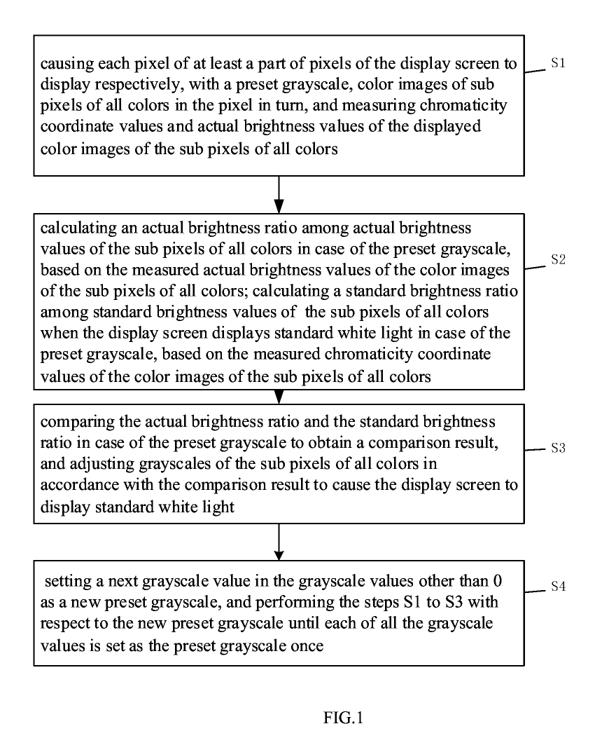

FIG. 1 is a general flow chart of a white balance adjustment method for a display screen provided by the present disclosure. Referring to FIG. 1, a white balance adjustment method for a display screen provided by an embodiment of the present disclosure may include following steps S1 to S3.

Step S1, causing each pixel of all pixels of the display screen to display respectively, with a preset grayscale, color images of sub pixels of all colors in the pixel in turn, and measuring chromaticity coordinate values and actual brightness values of the displayed color images of the sub pixels of all colors.

If the display screen includes sub pixels of three primary colors of RGB and the preset grayscale is set to 3, the step S1 particularly includes: causing each pixel of all of the pixels of the display screen to display respectively, with the 3^{rd} grayscale, a red image, a green image and a blue image in turn, and measuring the chromaticity coordinate values and the actual brightness values of the displayed color images of the display screen in these cases, respectively. Specifically, each of the pixels of the display screen includes a red sub pixel, a green sub pixel, and a blue sub pixel. The grayscale of all red sub pixels is preset as 3, while the grayscales of the sub pixels of other colors (the green sub pixels and the blue sub pixels) are both preset as 0. Thereby, all the pixels of the display screen may display, with the 3^{rd} grayscale, a red image. Then, the chromaticity coordinate value and the brightness value of the displayed red image of the red sub pixels are measured. The cases for a green image and a blue image are similar to the case for the red image as described above, and will not be repeated here.

The chromaticity coordinate value and the brightness value of the color image displayed by the display screen may be measured by, optionally but not limited to, a photometer.

Furthermore, the value of the grayscale may be set as follows: data is transmitted in 8-bit mode in a display, and 2⁸ grayscales with grayscale values ranging from 0 to 255 are set; or data is transmitted in 6-bit mode in a display, and 2⁶ grayscales with grayscale values ranging from 0 to 63 are set.

Step S2, calculating an actual brightness ratio among the actual brightness values of the sub pixels of all colors in case of the preset grayscale, based on the measured actual brightness values of the color images of the sub pixels of all colors; calculating a standard brightness ratio of among the standard brightness values of the sub pixels of all colors when the display screen displays standard white light in case of the preset grayscale, based on the measured chromaticity coordinate values of the color images of the sub pixels of all colors.

By way of example, when the display screen displays a red image, a green image and a blue image with the 3^{rd} grayscale in turn in the step S1, it is assumed that the actual brightness values of the display screen are measured as Lr1, Lg1 and Lb1, respectively, and thus the actual brightness ratio L1 among the actual brightness values of the sub pixels of RGB in case of this preset grayscale (i.e., the 3^{rd} grayscale) is: Lr1:Lg1:Lb1. It is assumed that the chromaticity coordinate values of the display screen are measured as Yr, Yg and Yb, respectively, and the standard brightness ratio L2 among the standard brightness values of the sub pixels of RGB is calculated as Lr2:Lg2:Lb2 in accordance with Yr, Yg and Yb when the display screen displays standard white light in case of the 3^{rd} grayscale.

As known by a person skilled in the art, a display screen with a certain configuration has a fixed gamut space, and thus a ratio of the three primary color coefficients of a standard white light is fixed. At this time, the obtained chromaticity coordinate values Yr, Yg and Yb are converted into three stimulus values, and then the brightness ratio of the three primary colors could be obtained by solving the equation of three stimulus values. When the standard white light is matched by adding and mixing three primary color sub pixels, the luminous flux (R) of the required three primary color lights is 1R lumen; (G) 1G lumen; and (B) 1B lumen. The ratio of 1R:1G:1B is defined as the relative brightness unit of the three stimulus values, that is, the standard brightness ratio L2 as mentioned above of Lr2:Lg2:Lb2.

S3, comparing the actual brightness ratio L1 and the standard brightness ratio L2 in case of the preset grayscale (i.e., the 3^{rd} grayscale) to obtain a comparison result, and adjusting grayscales of the sub pixels of all colors in accordance with the comparison result to cause the display screen to display standard white light (i.e., the display screen displays white balance in case of the preset grayscale). Specifically, the grayscales of the sub pixels of all colors are adjusted such that the actual brightness ratio L1 tends to be equal to the standard brightness ratio L2.

As can be seen from the forgoing, the white balance adjustment method for a display screen provided by the present embodiment adjusts the actual brightness values of the sub pixels of all colors simply by adjusting input data (i.e., the grayscales) thereof to adjust the actual brightness ratio of the sub pixels of all colors to reach the standard brightness ratio when the display screen displays standard white light. Compared with the prior art, it can not only achieve adjusting white balance without changing the parameters of the display screen, but also is applicable to various of display screens with different TFT characteristics and OLED characteristics.

Optionally, in the present embodiment, as shown in FIG. 1, the white balance adjustment method for a display screen further includes step of:

S4, setting a plurality of different preset grayscales in turn, and performing the above steps S1 to S3 with respect to each preset grayscale.

It will be appreciated that, by performing the steps S1 to S3 once, the display screen can display standard white light in case of a certain preset grayscale. The step S4 repeats the steps S1 to S3 with a different preset grayscale each time, thereby causing the display screen to be able to display standard white light in cases of multiple preset grayscales, respectively.

Further, optionally, the step S4 includes: setting a next grayscales value in the grayscale values other than 0 as a new preset grayscale, and performing the steps Si to S3 with respect to the new preset grayscale until each of all the grayscale values is set as the preset grayscale once; such an operation ensures that the display screen can display standard white light in case of all grayscales. In practice, as an option without limitation, it is assumed that a value of the grayscale may range from 0 to 255, and the initial value of the preset grayscale is preset as 1; each time when the steps S1 to S3 are repeated, the value of the preset grayscale is increased by 1 till it reaches 255.

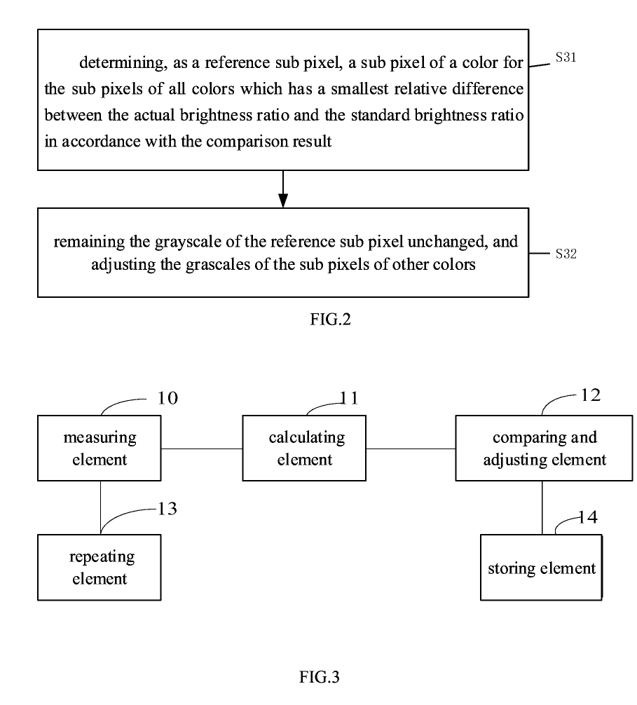

As shown in FIG. 2, optionally, the step S3 includes:

S31, determining, as a reference sub pixel, a sub pixel of a color for the sub pixels of all colors which has a smallest relative difference between the actual brightness ratio L1 and the standard brightness ratio L2 in accordance with the comparison result; and

S32, remaining the grayscale of the reference sub pixel unchanged, and adjusting the grayscales of the sub pixels of other colors.

By way of example, in the step S31, the actual brightness ratio L1=Lr1:Lg1:Lb1, and the standard brightness ratio L2=Lr2:Lg2:Lb2. The relative difference Ar of the red sub pixel may be calculated based on Lr1 and Lr2, the relative difference Ag of the green sub pixel may be calculated based on Lg1 and Lg2, and the relative difference Ab of the blue sub pixel may be calculated based on Lb1 and Lb2. The sub pixel corresponding to the minimum of Ar, Ag and Ab is selected as the reference sub pixel. For example, if Ab is the minimum, the blue sub pixel is selected as the reference sub pixel, the grayscale of the blue sub pixel will not be changed in the step S32 and only the grayscales of the red sub pixel and the green sub pixel are adjusted.

With the steps S31 and S32, the number of the variables to be adjusted may be reduced by one, and the process for adjusting white balance is simplified, thereby the efficiency of white balance adjustment may be improved.

As an option without limitation, the relative difference A of the sub pixel of each color (i.e., Ar, Ag or Ab) is calculated as follows: A=(P−P1)/P1,

where P is a proportion of the actual brightness value of a sub pixel of a color in the actual brightness values of the sub pixels of all colors; and P1 is a proportion of the standard brightness value of the sub pixel of this color in a standard brightness values of the sub pixels of all colors.

By way of example, as for the red sub pixel, Ar=(Pr−P1r)/P1r, wherein Pr=(Lr1)/(Lr1+Lg1+Lb1); and P1r=(Lr2)/(Lr2+Lg2+Lb2).

The relative difference A as calculated in the manner mentioned above can reflect the amount to be adjusted from the actual brightness value to the standard brightness value of the sub pixel of each color even more accurately, and thereby the reference sub pixel can be determined more accurately.

In addition, in the present embodiment, optionally, the step S3 further includes:

determining an adjusting direction to increase or reduce the grayscale of the sub pixel of each color in accordance with the comparison result, so as to adjust the grayscales of the sub pixel of each color based on the adjusting direction. For example, when the relative difference A for a sub pixel of a color is a positive value, the adjusting direction of the sub pixel of this color is decreasing. Similarly, when the relative difference A for a sub pixel of another color is a negative value, the adjusting direction of the sub pixel of this another color is increasing.

It may be appreciated that, in this manner, the adjustment may be performed rapidly based on the adjusting direction; and it is not required to first perform judgment artificially based on the actual brightness ratio L1 and the standard brightness ratio L2 and then perform adjustment. Thereby, the efficiency of adjusting white balance can be improved.

In addition, in the present embodiment, optionally, the method further includes: storing the adjusted grayscales of the sub pixels of all colors when the display screen displays standard white light for each preset grayscale in the grayscale values other than 0, so as to facilitate inquiring subsequently about adjusted grayscales of the sub pixels of all colors in case of a known grayscale for each pixel of the display screen, and inputting the respective adjusted grayscales as image data into the display screen to achieve white balance. Thereby, it is ensured that white balance of the display screen in case of any of the grayscales can be achieved rapidly by inquiring.

In practice, the grayscales of the sub pixels of all colors when the display screen displays standard white light respectively in case of individual preset grayscales may be stored in the form of a ROM table. By taking image data input initially as an address, the ROM table is searched using a look-up table method Finally, the output of the ROM table is used as the image data input into the display screen.

It should be noted that, although the step S1 causes each pixel of all the pixels of the display screen to display respectively, with a preset grayscale, color images of sub pixels of all colors in the pixel in turn, and measuring chromaticity values and actual brightness values of the displayed color images of the sub pixels of all colors in the present embodiment, the present disclosure is not limited thereto. In practice, the step S1 may causing each pixel of a part of the pixels of the display screen to display respectively, with a preset grayscale, color images of sub pixels of all colors in the pixel in turn, and measuring chromaticity values and actual brightness values of the displayed color images of the sub pixels of all colors.

FIG. 3 is a principle block diagram of a white balance adjustment system for a display screen provided by an embodiment of the present disclosure. Referring to FIG. 3, the white balance adjustment system for a display screen provided by the embodiment of the present disclosure includes a measuring element 10, a calculating element 11 and a comparing and adjusting element 12. The measuring element 10 is configured to cause each pixel of at least a part of pixels of the display screen to display respectively, with a preset grayscale, color images of sub pixels of all colors in the pixel in turn, and measure chromaticity values and actual brightness values of the displayed color images of the sub pixels of all colors. The calculating element 11 is configured to calculate an actual brightness ratio among the actual brightness values of the sub pixels of all colors in case of the preset grayscale, based on the measured actual brightness values of the color images of the sub pixels of all colors, and calculate a standard brightness ratio among the standard brightness values of the sub pixels of all colors when the display screen displays standard white light in case of the preset grayscale, based on the measured chromaticity coordinate values of the color images of the sub pixels of all color. The comparing and adjusting element 12 is configured to compare the actual brightness ratio and the standard brightness ratio to obtain a comparison result, and adjust grayscales of the sub pixels of all colors in accordance with the comparison result to cause the display screen to display standard white light.

Optionally, the white balance adjustment system for a display screen further includes a repeating element 13 which is configured to set a plurality of different preset grayscales and control the measuring element 10, the calculating element 11 and the comparing and adjusting element 12 to repeat working with respect to each preset grayscale.

Further, optionally, the repeating element 13 is configured to set all the grayscales as the preset grayscale in turn.

Optionally, the comparing and adjusting element 12 is configured to determine, as a reference sub pixel, a sub pixel of a color for the sub pixels of all colors which has a smallest relative difference between the actual brightness ratio and the standard brightness ratio in accordance with the comparison result, remain the grayscale of the reference sub pixel unchanged, and adjust the grayscales of the sub pixels of other colors.

Further, optionally, the comparing and adjusting element 12 is configured to calculate a relative difference A for a sub pixel of a color as follows: A=(P−P1)/P1; where P is a proportion of the actual brightness value of the sub pixel of the color in the actual brightness value of the sub pixels of all colors; and P1 is a proportion of the standard brightness value of the sub pixel of the color in the standard brightness values of the sub pixels of all colors.

In addition, optionally, the comparing and adjusting element 12 is further configured to determine an adjusting direction to increase or reduce the grayscale of the sub pixel of each color in accordance with the comparison result, so as to adjust the grayscales of the sub pixel of each color based on the adjusting direction. For example, when the relative difference A for a sub pixel of a color is a positive value, the adjusting direction of the sub pixel of this color is decreasing. Similarly, when the relative difference A for a sub pixel of another color is a negative value, the adjusting direction of the sub pixel of this another color is increasing.

Further, optionally, the white balance adjustment system for a display screen further includes a storing element 14 which is configured to store the adjusted grayscales of the sub pixels of all colors when the display screen displays standard white light for each preset grayscale in the grayscale values other than 0, so as to facilitate inquiring subsequently about respective adjusted grayscales of the sub pixels of all colors in case of a known grayscale for each pixel of the display screen, and inputting the respective adjusted grayscales as image data into the display screen to achieve white balance.

It should be noted that, although the measuring element 10 is configured to cause each pixel of all the pixels of the display screen to display respectively, with a preset grayscale, color images of sub pixels of all colors in the pixel in turn, and measure chromaticity values and actual brightness values of the displayed color images of the sub pixels of all colors in the present embodiment, the present disclosure is not limited thereto. In practice, the measuring element 10 may be configured to cause each pixel of a part of the pixels of the display screen to display respectively, with a preset grayscale, color images of sub pixels of all colors in the pixel in turn, and measure chromaticity values and actual brightness values of the displayed color images of the sub pixels of all colors.

The white balance adjustment system for a display screen provided by an embodiment of the present invention is a product corresponding to the white balance adjustment method for a display screen provided by the above embodiment. Therefore, technical contents related to the system may refer to the above embodiment, and will not be repeated here.

The present disclosure further provides a display apparatus which includes a display screen and a white balance adjustment system. The white balance adjustment system is the white balance adjustment system for a display screen provided by the above embodiment.

Specifically, the display apparatus includes but is not limited to an AMOLED display apparatus.

Specifically, the display apparatus further includes an image signal source for generating input data (i.e., grayscales) for all sub pixels. That is to say, the image signal source generates a video image with a corresponding resolution for a certain display apparatus. The image signal source includes but is not limited to: a key-debounce element, a data plus-minus element, a binary code-to-binary coded decimal code element (B-BCD element), a seven-segment scan-LED element, and a video generation element. The grayscales of the sub pixels of three colors with red, green and blue may be controlled and adjusted by using press keys. If the grayscales range from 0 to 63 (containing 0 and 63), the grayscales of the sub pixels of three colors with red, green and blue may be displayed by using a six-digit seven-segment LED.

The display apparatus provided by the embodiment of the present disclosure employs the white balance adjustment system for a display screen provided by the above embodiment as its white balance adjustment system. Thus, a novel display apparatus is provided.

The flow chart or the block diagram in the drawings illustrates possible architectures, functions and operations according to the system, the method and the computer program product of various embodiments of the present disclosure. In this regard, each block in the flow chart or the block diagram may represent a module, a program section, or a part of codes which contains at least one executable instruction for realizing the defined logic function. It should be noted that, in some alternative implementations, the functions indicated within the blocks may happen in an order different from that as indicated in the figures. For example, two blocks jointed in sequence may be performed in parallel in practice, or may be performed in reverse order, depending on the functions involved. It should be further noted that each block in the block diagram and/or flow chart and a combination of the blocks in the block diagram and/or flow chart may be implemented by a dedicated hardware-based system performing defined functions or operations, or by a combination of dedicated hardware and computer instructions.

The unit, element, step or module involved in the embodiments of the present disclosure may be implemented by software or hardware. The described unit, element, step or module may be provided in a processor. For example, the unit, element, step or module may be software program provided in a computer or a mobile smart apparatus, or a hardware apparatus provided separately. The names for these units, elements, steps or modules do not become a limitation for the units, elements, steps or modules themselves.

Obviously, the above implementations are exemplary implementations simply for illustrating the principle of the present invention. However, the present invention is not limited thereto. An ordinary person skilled in the art may make various modifications and variations without departing from the spirit and scope of the present invention. The present invention is intended to encompass these modifications and variations.

What is claimed is:

1. A white balance adjustment method for a display screen, comprising steps S1 to S3:
step S1, causing each pixel of at least a part of pixels of the display screen to display, with a preset grayscale, color images of sub pixels of all colors in the pixel in turn, and measuring chromaticity coordinate values and actual brightness values of the displayed color images of the sub pixels of all colors;
step S2, calculating an actual brightness ratio among actual brightness values of the sub pixels of all colors in case of the preset grayscale, based on the measured actual brightness values of the color images of the sub pixels of all colors; calculating a standard brightness ratio among standard brightness values of the sub pixels of all colors when the display screen displays standard white light in case of the preset grayscale, based on the measured chromaticity coordinate values of the color images of the sub pixels of all colors; and
step S3, comparing the actual brightness ratio and the standard brightness ratio in case of the preset grayscale to obtain a comparison result, and adjusting grayscales of the sub pixels of all colors in accordance with the comparison result to cause the display screen to display standard white light.

2. The white balance adjustment method of claim 1, wherein, in the step S1, causing each pixel of all pixels of the display screen to display, with a preset grayscale, color images of the sub pixels of all colors in the pixel in turn, and measuring chromaticity coordinate values and actual brightness values of the displayed color images of the sub pixels of all colors.

3. The white balance adjustment method of claim 1, wherein, each of the at least one pixel of the display screen comprises a red sub pixel, a green sub pixel, and a blue sub pixel, wherein the step S1 comprises:
setting a grayscale of the red sub pixel as the preset grayscale, setting a grayscale of each of the green sub pixel and the blue sub pixel as 0, displaying a red image, and measuring the chromaticity coordinate value and the actual brightness value of the displayed red image of the red sub pixel,
setting a grayscale of the green sub pixel as the preset grayscale, setting the grayscale of each of the red sub pixel and the blue sub pixel as 0, displaying a green image, and measuring the chromaticity coordinate value and the actual brightness value of the displayed green image of the green sub pixel, and
setting a grayscale of the blue sub pixel as the preset grayscale, setting the grayscale of each of the green sub pixel and the red sub pixel as 0, displaying a blue image, and measuring the chromaticity coordinate value and the actual brightness value of the displayed blue image of the blue sub pixel.

4. The white balance adjustment method of claim 1, wherein the step S3 comprises:
S31, determining, as a reference sub pixel, a sub pixel of a color for the sub pixels of all colors which has a smallest relative difference between the actual brightness ratio and the standard brightness ratio in accordance with the comparison result; and
S32, remaining the grayscale of the reference sub pixel unchanged, and adjusting the grayscales of the sub pixels of other colors.

5. The white balance adjustment method of claim 4, wherein a relative difference A for a sub pixel of a color is calculated as follows:
A=(P−P1)/P1
where P is a proportion of the actual brightness value of the sub pixel of the color in the actual brightness values of the sub pixels of all colors; and
P1 is a proportion of the standard brightness value of the sub pixel of the color in the standard brightness values of the sub pixels of all colors.

6. The white balance adjustment method of claim 1, wherein the step S3 further comprises:
determining an adjusting direction to increase or reduce the grayscale of the sub pixel of each color in accordance with the comparison result, so as to adjust the grayscale of the sub pixel of each color based on the adjusting direction.

7. The white balance adjustment method of claim 1, wherein, data is transmitted in 8-bit mode in the display screen, 2⁸ grayscales with grayscale values ranging from 0 to 255 are set, and the preset grayscale is one of the grayscale values 1 to 255; or
data is transmitted in 6-bit mode in the display screen, 2⁶ grayscales with grayscale values ranging from 0 to 63 are set, and the preset grayscale is one of the grayscale values 1 to 63.

8. The white balance adjustment method of claim 7, further comprising step of:
S4, performing the steps S1 to S3 once with respect to each of all the grayscale values.

9. The white balance adjustment method of claim 8, further comprising:
storing the adjusted grayscales of the sub pixels of all the colors with respect to all the grayscale values, so as to facilitate inquiring subsequently about respective adjusted grayscales of the sub pixels of all the colors, and inputting the respective adjusted grayscales as image data into the display screen to achieve white balance.

10. A white balance adjustment system for a display screen, comprising:
a measuring element configured to cause each pixel of at least a part of pixels of the display screen to display, with a preset grayscale, color images of sub pixels of all colors in the pixel in turn, and measuring chromaticity coordinate values and actual brightness values of the displayed color images of the sub pixels of all colors;
a calculating element configured to calculate an actual brightness ratio among actual brightness values of the sub pixels of all colors in case of the preset grayscale, based on the measured actual brightness values of the color images of the sub pixels of all colors; and calculating a standard brightness ratio among standard brightness values of the sub pixels of all colors when the display screen displays standard white light in case of the preset grayscale, based on the measured chromaticity coordinate values of the color images of the sub pixels of all colors; and
a comparing and adjusting element configured to compare the actual brightness ratio and the standard brightness ratio in case of the preset grayscale to obtain a comparison result, and adjusting grayscales of the sub pixels of all colors in accordance with the comparison result to cause the display screen to display standard white light.

11. The white balance adjustment system for a display screen of claim 10, wherein, the measuring element causes each pixel of all pixels of the display screen to display, with a preset grayscale, color images of the sub pixels of all colors in the pixel in turn, and measures chromaticity coordinate values and actual brightness values of the displayed color images of the sub pixels of all colors.

12. The white balance adjustment system for a display screen of claim 10, wherein, each of the at least one pixel of the display screen comprises a red sub pixel, a green sub pixel, and a blue sub pixel, wherein the measuring element is further configured to:
set a grayscale of the red sub pixel as the preset grayscale, setting a grayscale of each of the green sub pixel and the blue sub pixel as 0, display a red image, and measure the chromaticity coordinate value and the actual brightness value of the displayed red image of the red sub pixel,
set a grayscale of the green sub pixel as the preset grayscale, setting the grayscale of each of the red sub pixel and the blue sub pixel as 0, display a green image, and measure the chromaticity coordinate value and the actual brightness value of the displayed green image of the green sub pixel, and
set a grayscale of the blue sub pixel as the preset grayscale, setting the grayscale of each of the green sub pixel and the red sub pixel as 0, display a blue image, and measure the chromaticity coordinate value and the actual brightness value of the displayed blue image of the blue sub pixel.

13. The white balance adjustment system for a display screen of claim 10, wherein, the comparing and adjusting element is configured to determine, as a reference sub pixel, a sub pixel of a color for the sub pixels of all colors which has a smallest relative difference between the actual brightness ratio and the standard brightness ratio in accordance with the comparison result, remain the grayscale of the reference sub pixel unchanged, and adjust the grayscales of the sub pixels of other colors.

14. The white balance adjustment system for a display screen of claim 13, wherein, the comparing and adjusting element is configured to calculate a relative difference A for a sub pixel of a color as follows:
A=(P−P1)/P1
where P is a proportion of the actual brightness value of the sub pixel of the color in the actual brightness values of the sub pixels of all colors; and
P1 is a proportion of the standard brightness value of the sub pixel of the color in the standard brightness values of the sub pixels of all colors.

15. The white balance adjustment system for a display screen of claim 10, wherein, the comparing and adjusting element is further configured to determine an adjusting direction to increase or reduce the grayscale of the sub pixel of each color in accordance with the comparison result, so as to adjust the grayscales of the sub pixel of each color based on the adjusting direction.

16. The white balance adjustment system for a display screen of claim 10, wherein, data is transmitted in 8-bit mode in the display screen, 2⁸ grayscales with grayscale values ranging from 0 to 255 are set, and the preset grayscale is at least one of the grayscale values 1 to 255; or
data is transmitted in 6-bit mode in the display screen, 2⁶ grayscales with grayscale value ranging from 0 to 63 are set, and the preset grayscale is one of the grayscale values 1 to 63.

17. The white balance adjustment system for a display screen of claim 16, further comprising:
a repeating element configured to control the measuring element, the calculating element and the comparing and adjusting element to repeat their respective operations once with respect to each of all the grayscale values.

18. The white balance adjustment system for a display screen of claim 16, further comprising:
a storing element configured to store the adjusted grayscales of the sub pixels of all the colors with respect to all the grayscale values, so as to facilitate inquiring subsequently about respective adjusted grayscales of the sub pixels of all the colors, and inputting the respective adjusted grayscales as image data into the display screen to achieve white balance.

19. A display apparatus, comprising a display screen and a white balance adjustment system, wherein the white balance adjustment system is the white balance adjustment system for a display screen of claim 10.
